(19) United States
(12) Patent Application Publication
(10) Pub. No.: US 2023/0171916 A1
(43) Pub. Date: Jun. 1, 2023

(54) FLUID MOVEMENT THROUGH A WALL INSET

(71) Applicant: HEWLETT-PACKARD DEVELOPMENT COMPANY, L.P., Spring, TX (US)

(72) Inventors: Andrew L. Wiltzius, Fort Collins, CO (US); Robert Lee Crane, Fort Collins, CO (US)

(73) Assignee: HEWLETT-PACKARD DEVELOPMENT COMPANY, L.P., Spring, TX (US)

(21) Appl. No.: 17/922,430

(22) PCT Filed: Apr. 30, 2020
(86) PCT No.: PCT/US2020/030694

§ 371 Date: Oct. 31, 2022

(51) Int. Cl. H05K 7/20; G06F 1/20

(52) U.S. Cl. CPC H05K 7/20145; G06F 1/20

(57) ABSTRACT

In an example implementation according to aspects of the present disclosure, an electronic assembly comprises a chassis including a wall and a component section. The electronic assembly comprises a printed circuit board (PCB) having an inset that forms a gap between the PCB and the wall of the chassis to enable fluid to flow along the wall of the chassis from a first region of the electronic assembly located adjacent to a first side of the PCB to a second region of the electronic assembly located adjacent to a second side of the PCB. The electronic assembly also includes a fluid mover to move fluid, via the inset, from the first region of the electronic assembly to the component section located in the second region of the electronic assembly.

### BACKGROUND

Electronic devices, including computer systems, include a chassis to enclose computing components. The computing components may include a printed circuit board (PCB) with a number of electronic components mounted to the board. The computing components may also include expansion cards, such as peripheral component interconnect express (PCIe) cards.

### BRIEF DESCRIPTION OF THE DRAWINGS

Many aspects of the disclosure can be better understood with reference to the following drawings. While several examples are described in connection with these drawings, the disclosure is not limited to the examples disclosed herein.

FIGS. 1A-1B illustrate an electronic assembly, according to an example;

FIGS. 2A-2B illustrate a perspective view of a computing assembly, according to an example;

FIG. 3 illustrates an operation to cool a component section in a chassis, according to another example;

FIG. 4 illustrates an alternative operation to cool a component section in a chassis, according to another example;

FIG. 5 illustrates a block diagram of a computing device to control fluid movement through a wall inset, according to an example; and

FIG. 6 illustrates a flow diagram of a method to control fluid movement through a wall inset, according to some examples.

### DETAILED DESCRIPTION

Electronic devices are continuously being upgraded to improve performance, such as video and/or gaming performance when using a computing device. One such upgrade includes installing expansion cards, such as peripheral component interconnect express (PCIe) expansion cards. The expansion cards may be installed on a printed circuit board (PCB) using expansion slots. These expansion cards may be mounted on or near the PCB. Furthermore, the expansion cards and the mountable PCB may be enclosed in the electronic device by a computing chassis.

As expansion cards use more power and thus generate more heat, it has become challenging to cool the expansion cards and other computing components enclosed in the computing chassis. Furthermore, some electronic devices, such as workstations, may support the use of multiple expansion cards within a single system. During operation, the expansion cards and other computing components can generate heat inside the chassis. Therefore, ventilation systems have been implemented to cool the expansion cards and other components in the computing chassis. More specifically, the ventilation systems provide air that has a lower temperature relative to the emissive heat resulting from the operation of the expansions cards.

In one prior solution, additional air movers have been provided, such as in a region above the expansion cards enclosed in the computing chassis. In this solution, the heated air within the computing chassis may be expelled out a side panel of the computing chassis or through a rear or front of the computing chassis. However, this solution takes up additional space within the computing chassis, while adding a limited amount of additional cooling of expansion cards within the computing chassis.

While some expansion cards enable ventilation in a rear bulkhead of the computing chassis, a significant portion of the heated air may be left inside the computing chassis for a system-level cooling solution to manage, such as a chassis exhaust fan. The heated air within the computing enclosure generally is recirculated within the computing enclosure. Additional heat may also be circulated by the cards themselves due to convection, which can affect the performance and longevity of the computing components.

Other solutions for improving the cooling of the expansion cards and expelling heated air from within the computer enclosure have included providing additional air movers in slots next to the expansion cards which generate heat. While providing additional air movers in the slots may cool the expansion cards to a degree, this solution takes up slots which may otherwise be used to install additional expansion cards. Therefore, using cooling systems in the slots next to the expansion cards generating heat sacrifices the use of the additional expansion cards within the slots occupied by the air movers. Further, adding the air movers above the expansion cards can occupy space that may have been used for cabling and interconnects, such as multiple-lane near-range communication links, dual power and signal connectors, interfaces for Virtual Reality (VR) devices, etc.

In an example where a graphics card uses two or more axial fans that blow in a direction perpendicular to the graphics card's PCB, the fan closest to a side wall of the system (e.g., the fan closest to the front wall of the enclosure with a vent) gets cooler air from the side wall (i.e., front) of the computing enclosure. However, the fan furthest from the side wall (e.g., the fan closest to the rear wall of the enclosure) of the system gets preheated air from the fans closer to the side wall of the system with the vent. This can increase the operating temperature for the fan furthest from the side wall of the system having the vent, such as the rear most fan.

The exposure to the increased temperature can shorten the life and decrease the efficiency of the fan furthest from the side wall of the system having the vent. Providing cooler air to fans that are further away from the side wall of the enclosure having a vent would help ensure that the components that are not as close to other components to the sides walls having vents would be able to be exposed to cooler air from outside of the computing system and in turn which assists the components to continue to operate reliably.

Various examples described herein relate to an electronic assembly which comprises a chassis including a wall and a component section. The electronic assembly comprises a PCB having an inset that forms a gap between the PCB and the wall of the chassis to enable fluid to flow along the wall of the chassis from a first region of the electronic assembly located adjacent to a first side of the PCB to a second region of the electronic assembly located adjacent to a second side of the PCB. The electronic assembly also includes a fluid mover to move fluid, via the inset, from the first region of the electronic assembly to the component section located in the second region of the electronic assembly.

In other examples described herein, a computer assembly comprises a graphics card and a motherboard located below the graphics card. The motherboard comprises a connectable interface to the graphics card and a rear inset which forms an air gap between the motherboard and a rear wall of the computer assembly to enable air to flow from a region below the motherboard to a region above of the motherboard along the rear wall of the computer assembly. The computer assembly further comprises an air mover device to move air through a first channel between the region below the motherboard and the rear inset. The air is directed from the region below the motherboard toward the graphics card located in the region above the motherboard.

In yet another example, a computer enclosure comprises a PCB located between a first fluid region and a second fluid region. The computer enclosure comprises an internal chassis located in the second fluid region and adjacent to the PCB. The computer enclosure also comprises an inset which forms a fluid gap between the PCB and a wall of the computer enclosure which enables fluid to flow from the first fluid region to the second fluid region along the wall of the computer enclosure. The computer enclosure also comprises a baffle to move fluid from the first fluid region to the internal chassis located in the second fluid region along the wall of the computer enclosure.

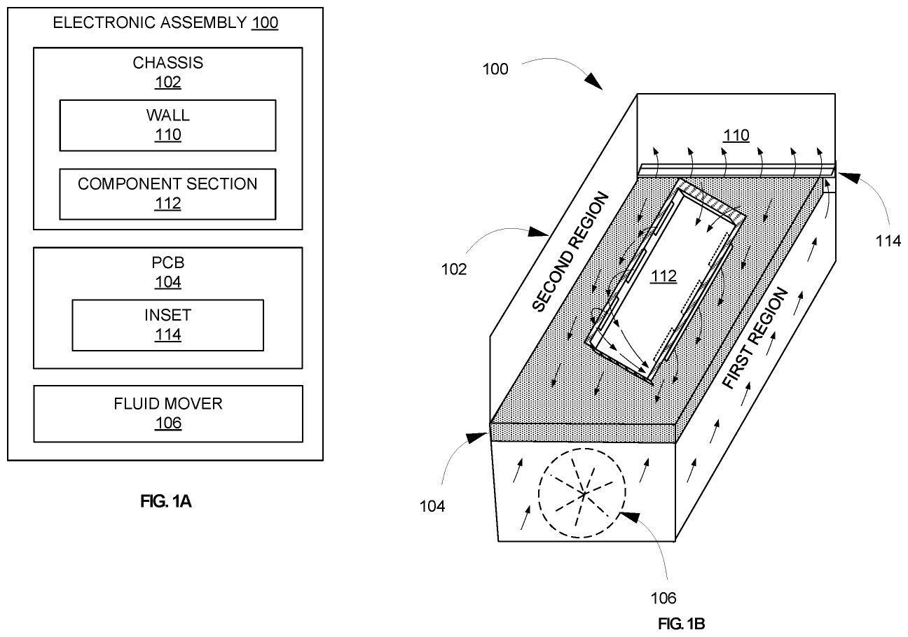

FIGS. 1A-1B illustrate an electronic assembly, according to an example. Electronic assembly 100 includes chassis 102, PCB 104, and fluid mover 106. Chassis 102 includes wall 110 and component section 112. PCB 104 includes inset 114. For purposes of the present discussion, the term “fluid” may refer to any substance that yields easily to external pressure. Examples of fluid may include air, liquid, or gas.

As indicated in FIG. 1B, electronic assembly 100 also includes a first region located on one side of PCB 104 and a second region located on another side of PCB 104. The first region and the second region of electronic assembly 100 are connected by inset 114 and may each contain fluid. The fluids may have different temperatures. For example, the fluid in the first region of electronic assembly 100 may contain fluid with a lower temperature (e.g., cooler air) than the fluid contained in the second region of electronic assembly 100, and vice versa.

In some examples, the first region may include a region below PCB 104 and the second region may include a region above PCB 104. However, in other examples, the first region may include a region to a front or side of PCB 104 and the second region may include a region to a back or opposite side of PCB 104.

Chassis 102 may be a structure which encloses the elements included in electronic assembly 100. Chassis 102 includes multiple walls, such as wall 110 to enclose the elements of electronic assembly 100. In some examples, wall 110 includes a rear wall of chassis 102. However, in other examples, wall 110 may be a side wall, a front wall, a top wall, or a bottom wall. For the purposes of this example, wall 110 is a wall which is located adjacent to inset 114.

As illustrated in FIGS. 1A-1B, chassis 102 may house component section 112, PCB 104, inset 114, and fluid mover 106. PCB 104 may be housed by chassis 102 as part of a motherboard section. Chassis 102 may also enclose a variety of other computing components, such as disk drives, power supplies, cooling systems, etc. Chassis 102 may come in a variety of sizes and shapes. The size and shape of chassis 102 may be designed to accommodate the form factor in which PCB 104 is installed within electronic assembly 100.

Component section 112 may include an expansion card or a graphics card. The expansion card or graphics card may be mounted in chassis 102 using expansion slots. The expansion slots may include a connection interface that is included with a motherboard section. Furthermore, the expansion slots may be mounted on PCB 104. In some scenarios, component section 112 may comprise a PCIe card. However, there is no intent to limit the types of slots and/or cards referred herein to PCIe slots and PCIe cards, respectively. Thus, references made in this description to PCIe cards, expansion cards, graphics cards, and the like, are intended to refer generally to any appropriate respective type of expansion card interface.

In some scenarios, component section 112 may include a plurality of expansion cards. The plurality of expansion cards may be mounted to PCB 104 using multiple expansion slots on a PCB connection interface. Further in this scenario, component section 112 may include additional fluid mover sections, such as fans. The additional fluid mover sections may be mounted by a select few of the expansion slots and may be used to pull fluid from inset 114 toward the expansion cards and/or the connection interface on PCB 104. Furthermore, the additional fluid mover may be mounted in such a way as to draw cooler fluid toward the expansion cards.

Component section 112 may be housed in an internal enclosure within chassis 102. For example, component section 112 may be housed in a box which may be mounted on PCB 104 or some other element within electronic assembly 100. In this scenario, the additional fluid mover sections discussed above may be mounted on the enclosure housing component section 112. The enclosure housing component section 112 may also include vents or cooling systems to facilitate additional cooling of component section 112.

PCB 104 includes the printed circuit assembly in electronic assembly 100. PCB 104 may include central processing unit(s), a memory controller, and input/output chipset. PCB 104 may be included on a motherboard section. The motherboard section may be a section in which the motherboard is mounted to a wall (i.e., other than wall 110), such as a side wall of chassis 102. In this example, the motherboard may have a designated section which is defined by fasteners to secure the motherboard to chassis 102.

PCB 104 is located adjacent to component section 112 and in some cases, is coupled to component section 112 using a connection interface or some other coupling mechanism. For example, PCB 104 may include expansion slots and other interface connectors for installing expansion cards and memory cards, such as PCIe cards, and other devices such as heat sinks for cooling the processors. These devices are generally located on the surface of PCB 104, such as on the top surface of PCB 104. However, the devices may also be located on a bottom surface or side surface of PCB 104.

In some examples, PCB 104 may be lined with a thermal layer on a surface located in the first region (e.g., a cooler region) of chassis 102. This allows the cooler fluid contained in the first region of chassis 102 to remain cool and not be heated by power used by PCB 104. As a result, when fluid contained in the first region is pushed across the surface of PCB 104 toward inset 114, heat from PCB 104 does not interact with the fluid and increase the temperature of the fluid in the first region.

Referring still to the example electronic assembly 100 of FIGS. 1A-1B, inset 114 forms a gap between PCB 104 and wall 110 of chassis 102. PCBs, such as motherboards, generally extend to a wall of a chassis, such as wall 110 of chassis 102. Therefore, there is very little room for any fluid to escape between wall 110 and PCB 104 from the first region of electronic assembly 100 to the second region of electronic assembly 100. However, electronic assembly 100 illustrates an inset 114 is formed by moving PCB 104 away from wall 110 of chassis 102 to form a gap. For example, PCB 104 may be moved away from wall 110 by an order of 4-6 mm. The gap formed by inset 114 enables fluid to flow from the first region to the second region in electronic assembly 100. For example, the fluid may flow from a region below PCB 104 to a region above PCB 104, in which component section 112 may be located.

In other examples, PCB 104 may be contoured or structurally designed to create inset 114 on an edge of PCB 104 adjacent to wall 110. For example, PCB 104 may have a portion cut out on an edge located next to a rear wall which allows fluid from underneath PCB 104 to be pushed upward (such as toward PCIe cards) located above PCB 104. However, in other examples, wall 110 may be contoured or structurally designed to create inset 114. For example, wall 110 may contoured outward in a location where wall 110 and PCB 104 would otherwise have touched. Like the previous examples, this allows the fluid from the first region to flow toward component section 112 in the second region.

Referring still to the example electronic assembly 100 of FIGS. 1A-1B, fluid mover 106 may include a fan (e.g., axial fan, centrifugal fan, etc.), a blower, a baffle, or any other device capable of providing external pressure to fluids (i.e., air, liquids, etc.) which results in the fluid being moved from one region to another within the enclosure of electronic device 100. In some examples, the cooler fluid is moved by fluid mover 106 from a region below PCB 104 to a region above PCB 104 through inset 114. However, fluid mover 106 may be used to move fluid from a region other than a region below PCB 104 to another region adjacent to PCB 104. For example, component section 112 may be located in a region to the side of PCB 104. In this example, fluid mover 106 may move fluid from a region to a first side of PCB 104 to a region to the opposite side of PCB 104 in which component section 112 is located.

In some examples, fluid mover 106 may be placed on a third region of electronic assembly 100. In this example, the third region is located near the opposite side of PCB 104 from inset 114, such as to the front of chassis 102 when inset 114 is located at the rear of PCB 104 and/or near a rear wall of chassis 102. In this example, fluid mover 106 is used to push fluid from a third region of electronic assembly 100 toward inset 114 through the first region. Once the fluid reaches inset 114, the fluid is pushed into the second region of electronic assembly 100 in which component section 112 is located.

For example, a fan may be placed in a front region 110 of electronic assembly 100. The fan may then push cooler air past the bottom of PCB 104 (i.e., through the first region) and toward inset 114 located in the back region 110 of electronic assembly 100. Once the cold air reaches inset 114, it would then be pushed through inset 114 and into the region above PCB 104 (i.e., the second region). This allows cool air to flow across the top surface of PCB 104 and cool component section 112 located on top of PCB 104.

In other examples, fluid mover 106 may be placed in the first region below PCB 104 and push fluid from the first region toward inset 114 and into the second region. For example, a blower or baffle may be placed in a location underneath PCB 104. In this example, cooler air from the first (i.e., lower) region may be pushed through inset 114 to the second (i.e., upper) region to cool component section 112.

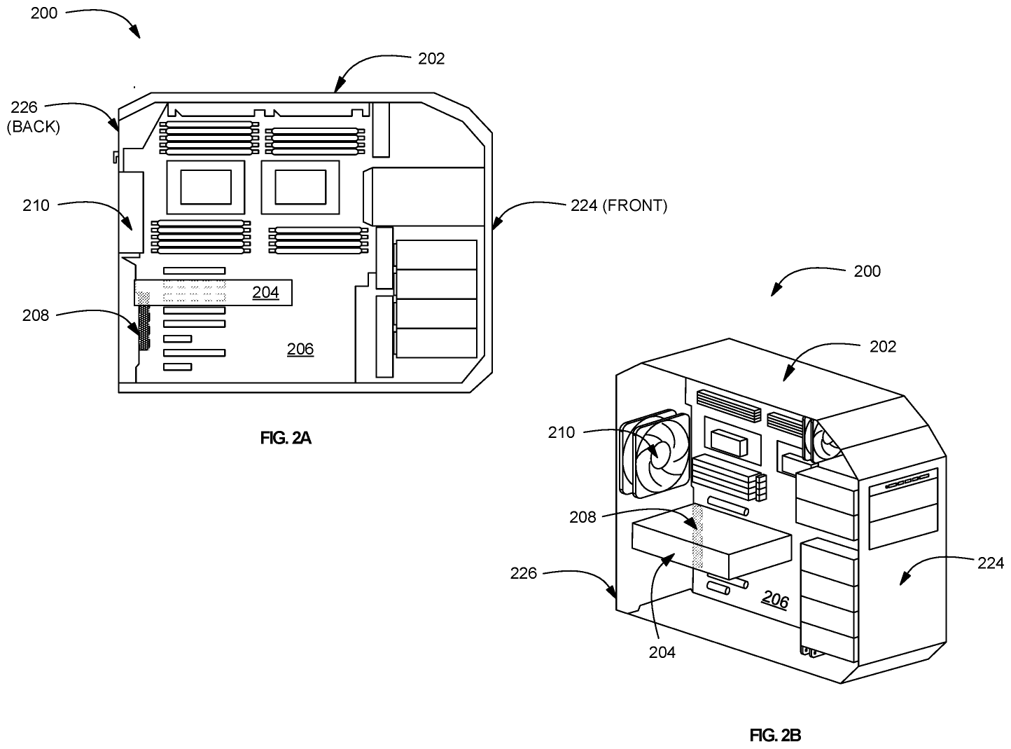

FIGS. 2A-2B illustrate a perspective view of a computing assembly, according to an example. Computing assembly 200 may be an example of electronic assembly 100 from FIG. 1. However, computing assembly 200 may differ in form or structure from electronic assembly 100. Referring to FIGS. 2A-2B, computing assembly 200 includes computer enclosure 202, one or more graphics cards 204, motherboard 206, motherboard inset 208, and fan 210. Computing assembly 200 also includes a lower (under side) region of motherboard 206 (not shown) and an upper (top side) region of motherboard 206. The components shown in FIG. 2A are on the upper region of motherboard 206. Computing assembly 200 further includes first side wall 224 and second side wall 226.

In this example, motherboard 206 has been contoured to form motherboard inset 208. Therefore, motherboard inset 208 creates a fluid gap between motherboard 206 and second side wall 226 of computing assembly 200. The fluid gap allows fluid of one temperature from the lower region of motherboard 206 to flow to the upper region of motherboard 206, which may have a different temperature than the fluid in the lower region of motherboard 206.

In this example scenario, the system airflow is from first side wall 224 to second side wall 226, or FRONT to BACK. The lower region of motherboard 206 includes cooler air than the upper region of motherboard 206. The lower region of motherboard 206 may have cooler air than the air in the back region of motherboard 206 near side wall 226 based on where the vents are located, for example. The warmer air in the back region of motherboard 206 may be caused by the power used by graphics cards 204 and distance from the vents. Graphics cards 204 may be mounted to motherboard 206 using a connection interface and/or expansion card slots. The expansion card slots may be occupied by additional air moving devices along with graphics cards 204. Although not illustrated in FIGS. 2A-2B, graphics cards 204 may be housed in an internal chassis. The internal chassis may be a box or structure to house graphics cards 204. The internal chassis may include vents or other cooling systems which may be used to pull cooler air from the lower region of motherboard 206 toward the upper region of motherboard 206 via motherboard inset 208.

Referring still to FIGS. 2A-2B, motherboard inset 208 formed at the rear edge of motherboard 206 may enable cooler air to flow through motherboard inset 208 from the lower region of motherboard 206 to the upper region of motherboard 206 using fan 210. Although fan 210 is located near second side wall 226 in this example scenario, fan 210 may be located closer to first side wall 224 or under motherboard 206

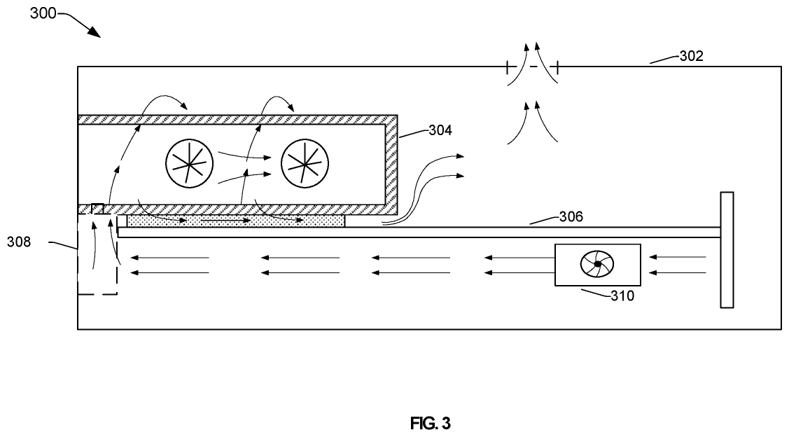

FIG. 3 illustrates an operation of a computing assembly to cool a component in a chassis, according to another example. Computing assembly 300 includes chassis 302, PCIe expansion card 304, motherboard 306, inset 308, and blower 310. Blower 310 is located in an area below motherboard 306. As illustrated by the arrows, the cooler air is moved through a first channel between the area below motherboard 306 and rear inset 308 by blower 310. Once the cooler air reaches inset 308, the cooler air is directed through a second channel between rear inset 308 and PCIe expansion card 304 located in the area above motherboard 306. The air may then be pushed through rear inset 308 toward PCIe expansion card 304 by the air pressure resulting from blower 310 moving the cooler air toward rear inset 308. In this example scenario, PCIe expansion card 304 also includes additional fans which may further pull the cooler air through the second channel between rear inset 308 and PCIe expansion card 304. In this example, as the cooler air is pushed into the region above motherboard 306, the pressure within the upper region of chassis 302 may increase and warmer air may be expelled from an opening in chassis 302, such as through a vent. However, in other examples, the additional fans located on PCIe card 304 may also be used to direct fluids toward a vent in chassis 302.

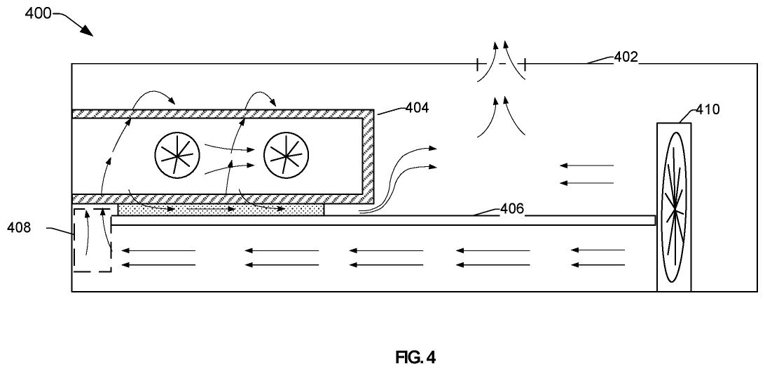

FIG. 4 illustrates an alternative operation of a computing assembly to cool a component in a chassis, according to another example. Computing assembly 400 includes chassis 402, PCIe expansion card 404, motherboard 406, rear inset 408, and front fan 410. As illustrated by the arrows, the cooler air is moved by front fan 410 through a first channel between fan 410 and rear inset 408. The first channel is located below motherboard 406. Once the cooler air reaches rear inset 408, the cooler air is pushed up toward PCIe expansion card 404 via a pressure build-up in the rear of chassis 402 near rear inset 408. Like FIG. 3, the example operation illustrated in FIG. 4 includes a PCIe expansion card with additional fans which may further pull the cooler air from the region below motherboard 406 towards the region above motherboard 406 where PCIe expansion card 404 is located.

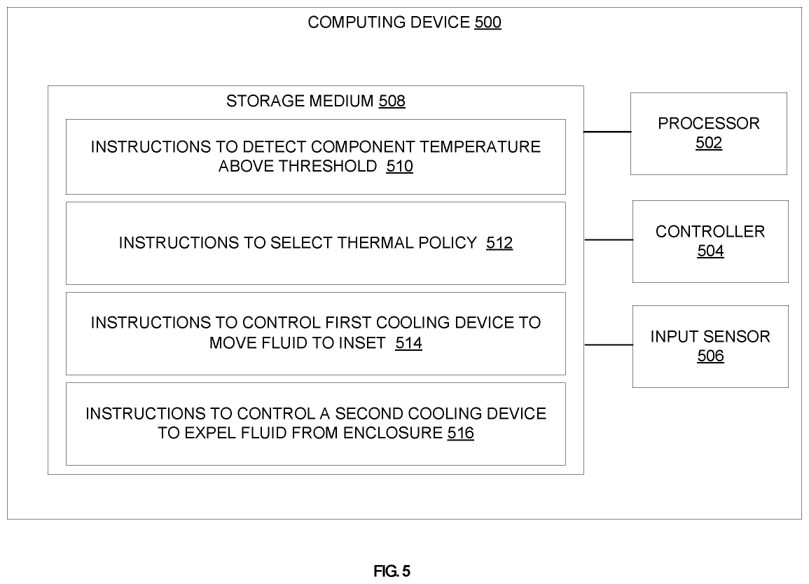

FIG. 5 illustrates a block diagram of a computing device to control fluid movement through a wall inset, according to an example. Computing device 500 includes processor 502, controller 504, input sensor 506, and storage medium 508. As an example of computing device 500 performing its operations, storage medium 508 may include instructions 510-516 that are executable by processor 502. Thus, storage medium 508 can be said to store program instructions that, when executed by processor 502, implement the components of computing device 500.

In particular, the executable instructions stored in storage medium 508 include, as an example, instructions 510 to detect, via input sensor 506, that a component temperature is above a threshold temperature level. The executable instructions stored in storage 508 include, as an example, instructions 512 to select a thermal policy for computing device 500 based on the detection that the component temperature is above the threshold. The thermal policy may indicate which fluid movers should be used to cool a component, what speed and direction the fluid movers should use to move the fluid, etc. The executable instructions stored in storage medium 508 also include, as an example, instructions 514 to control, by controller 504, a first cooling device to move fluid toward an inset. The executable instructions stored in storage medium 508 also include, as an example, instructions 516 to control, by controller 504, a second cooling system to expel fluid from the enclosure of computing device 500.

Storage medium 508 represents any number of memory components capable of storing instructions that can be executed by processor 502. As a result, a memory system may be implemented in a single device or distributed across devices. In some examples, storage medium 508 may be a non-transitory storage medium, where the term “non-transitory” does not encompass transitory propagating signals. Processor 502 may be a central processing unit (CPU), a semiconductor-based microprocessor, and/or other hardware devices suitable for retrieval and execution of instructions stored in computer-readable storage medium 508. Processor 502 represents any number of processors capable of executing instructions stored by storage medium 508. Storage medium 508 may be fully or partially integrated in the same device as processor 502, or storage medium 508 may be separate but accessible to the same device as processor 502.

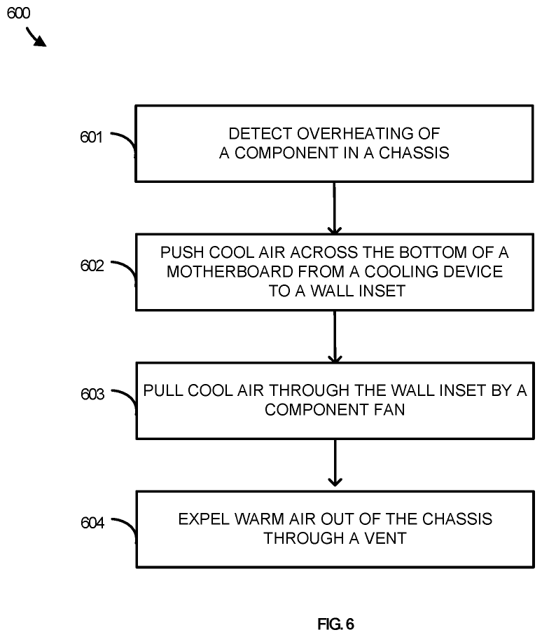

FIG. 6 illustrates a flow diagram illustrating an example method 600 to cool a component in a chassis, according to some examples. Method 600 is associated with examples discussed herein with regard to FIGS. 1-5, and details of the operations shown in this method can be found in the related discussion of such examples. Some or all of the blocks of method 600 may be implemented in program instructions in the context of a component or components of an application used to carry out the cooling of the component within the chassis for an electronic assembly.

Although the flow diagram of FIG. 6 shows a specific order of execution, the order of execution may differ from that which is depicted. For example, the order of execution of two of more blocks shown in succession by be executed concurrently or with partial concurrence. All such variations are within the scope of the present disclosure.

Referring parenthetically to the blocks in FIG. 6, method 600 provides detecting that a component of a chassis is overheating, at block 601. The overheating of the component may be detected by a thermal sensor, such as input sensor 506 from FIG. 5, detecting that a temperature of the air in a proximate location to the component or a temperature of the surface of the component is above a threshold temperature. The thermal sensor may then communicate that the component is overheating to a controller within the chassis, such as controller 504 from FIG. 5. The controller may be coupled to a blower (e.g., blower 310 from FIG. 3) or a fan (e.g., fan 410 from FIG. 4).

Method 600 further includes that cooler air from a region below a motherboard is then pushed by a cooling device across the bottom of the motherboard and through a wall inset of the motherboard, in which the cool air is pushed toward a component located in a region above the motherboard, at block 602. The cooling device may include a blower, such as blower 310 from FIG. 3. The cooling device may alternatively include a baffle or a fan, such as fan 410 from FIG. 4. The cooling device may be directed to push the cool air across the bottom of the motherboard by a controller coupled to the cooling device, such as controller 504 from FIG. 504.

Method 600 provides that a fan on the component located in a region above the motherboard may also pull cool air through the wall inset of the motherboard from the region below the motherboard, at block 603. The fan on the component may include a fan on a graphic card or PCIe card, such as PCIe card 304 or PCIe card 404. The fan may be directed by a controller (e.g., controller 506) to direct the fan to draw the cool air from the wall inset. At block 604, method 600 provides that warm air from the region above the motherboard is expelled out of the chassis and away from the component through a vent. The air may be expelled by the fan included on the component and/or by a pressure build up in the region above the motherboard.

The functional block diagrams, operational scenarios and sequences, and flow diagrams provided in the Figures are representative of example systems, environments, and methodologies for performing novel aspects of the disclosure. While, for purposes of simplicity of explanation, methods included herein may be in the form of a functional diagram, operational scenario or sequence, or flow diagram, and may be described as a series of acts, it is to be understood and appreciated that the methods are not limited by the order of acts, as some acts may, in accordance therewith, occur in a different order and/or concurrently with other acts from that shown and described herein. Those skilled in the art will understand and appreciate that a method could alternatively be represented as a series of interrelated states or events, such as in a state diagram. Moreover, not all acts illustrated in a methodology may be included as a novel example.

It is appreciated that examples described may include various components and features. It is also appreciated that numerous specific details are set forth to provide a thorough understanding of the examples. However, it is appreciated that the examples may be practiced without limitations to these specific details. In other instances, well known methods and structures may not be described in detail to avoid unnecessarily obscuring the description of the examples. Also, the examples may be used in combination with each other.

Reference in the specification to “an example” or similar language means that a particular feature, structure, or characteristic described in connection with the example is included in at least one example, but not necessarily in other examples. The various instances of the phrase “in one example” or similar phrases in various places in the specification are not necessarily all referring to the same example.

What is claimed is:

1. An electronic assembly comprising:
a chassis including a wall and a component section;
a printed circuit board (PCB) having an inset that forms a gap between the PCB and the wall of the chassis to enable fluid to flow along the wall of the chassis from a first region of the electronic assembly located adjacent to a first side of the PCB to a second region of the electronic assembly located adjacent to a second side of the PCB; and
a fluid mover to move fluid, via the inset, from the first region of the electronic assembly to the component section located in the second region of the electronic assembly.

2. The electronic assembly of claim 1, wherein the chassis houses a component at the component section, the PCB at a motherboard section, and the fluid mover.

3. The electronic assembly of claim 2, wherein the component comprises a graphics card.

4. The electronic assembly of claim 1, wherein the component section further includes an additional fluid mover to pull fluid through the inset to the second region of the electronic assembly.

5. The electronic assembly of claim 1, wherein the PCB comprises a motherboard.

6. The electronic assembly of claim 1, wherein the fluid mover comprises a fan placed in a third region of the electronic assembly which is located on an opposite side of the PCB from the inset, wherein the fan pushes fluid to the inset from a vent in the chassis located adjacent to the third region of the electronic assembly.

7. The electronic assembly of claim 1, wherein the fluid mover comprises a blower located in the first region of the electronic assembly, and wherein the blower pushes fluid to the inset from the first region of the electronic assembly.

8. The electronic assembly of claim 1, wherein the fluid mover comprises a baffle located in the first region of the electronic assembly, and wherein the baffle pushes fluid to the inset from the first region of the electronic assembly.

9. The electronic assembly of claim 1, wherein a surface of the PCB located adjacent to the first region of the electronic assembly comprises an insulated layer to reduce heat transfer from the PCB to fluid in the first region of the electronic assembly.

10. The electronic assembly of claim 1, wherein the first region of the electronic assembly comprises a region located below the PCB and the second region of the electronic assembly comprises a region located above the PCB.

11. A computer assembly comprising:
a graphics card;
a motherboard located below the graphics card comprising a connectable interface to the graphics card and comprising a rear inset which forms an air gap between the motherboard and a rear wall of the computer assembly to enable air to flow from a region below the motherboard to a region above of the motherboard along the rear wall of the computer assembly; and
an air mover device to move air through a first channel between the region below the motherboard and the rear inset, wherein the air is directed from the region below the motherboard toward the graphics card located in the region above the motherboard.

12. The computer assembly of claim 11, further comprising a second air mover device to move air through a second channel between the rear inset and the region above the motherboard, wherein the air is directed from the rear inset toward the graphics card located in the region above the motherboard.

13. The computer assembly of claim 11, wherein the graphics card comprises a peripheral component interconnect express (PCIe) card and wherein the motherboard having the connectable interface to the graphics card comprises the motherboard having a PCIe connectable interface to the PCIe card.

14. The computer assembly of claim 13, wherein the air mover device directs the air through a second channel between the rear inset and the region above the motherboard having the PCIe connectable interface to the PCIe card.

15. A computer enclosure comprising:
a printed circuit board (PCB) located between a first fluid region and a second fluid region;
an internal chassis located in the second fluid region and adjacent to the PCB;
a wall inset which forms a fluid gap between the PCB and a wall of the computer enclosure which enables fluid to flow from the first fluid region to the second fluid region along the wall of the computer enclosure; and
a baffle to move fluid from the first fluid region to the internal chassis located in the second fluid region through the wall inset of the computer enclosure.
